(19) United States
(12) Patent Application Publication
(10) Pub. No.: US 2008/0302482 A1
(43) Pub. Date: Dec. 11, 2008

(54) SUBSTRATE PROCESSING APPARATUS

(75) Inventors: Tae-Hyung HWANG, Seoul (KR); Hyung-Il JEON, Incheon-city (KR); Nam-Seok ROH, Seongnam-si (KR); Sang-Il KIM, Yongin-si (KR)

Correspondence Address: CANTOR COLBURN, LLP, 20 Church Street, 22nd Floor, Hartford, CT, 06103, US

(73) Assignee: SAMSUNG ELECTRONICS CO., LTD., Suwon-si (KR)

(21) Appl. No.: 11/969,576

(22) Filed: Jan. 4, 2008

(30) Foreign Application Priority Data
Jun. 5, 2007 (KR) 10-2007-0055111

(51) Int. Cl. C23F 1/08; C23C 14/34; C23C 16/00

(52) U.S. Cl. 156/345.1; 204/298.01; 118/715

(57) ABSTRACT

A substrate processing apparatus includes a substrate processing part which processes a substrate and a particle remover which generates an electric field. The particle remover generates the electric field adjacent to a sidewall of a chamber of the substrate processing apparatus, and the electric field guides particles formed during which the substrate is processed, to prevent the particles from being attached onto the sidewall of the chamber. Thus, the substrate processing apparatus prevents defects of the substrate due to the particles, thereby improving product yield and productivity and reducing a manufacturing cost thereof.

This application claims priority to Korean Patent Application No. 2007-55111 filed on Jun. 5, 2007, and all the benefits accruing therefrom under 35 U.S.C. §119, the contents of which in its entirety are herein incorporated by reference.

### BACKGROUND OF THE INVENTION

1. Field of the Invention

The present invention relates to a substrate processing apparatus. More particularly, the present invention relates to a substrate processing apparatus capable of improving a product yield.

2. Description of the Related Art

A conventional substrate processing apparatus, such as a sputtering apparatus, a plasma-enhanced chemical vapor deposition apparatus, a dry etching apparatus, etc., is applied to form or pattern a thin film using plasma, and is especially widely applied to processes for a semiconductor or a liquid crystal display (“LCD”) panel.

The conventional substrate processing apparatus includes a chamber, a susceptor on which a substrate is disposed thereon, and an electrode part facing the susceptor while interposing the substrate therebetween. The susceptor, the substrate and the electrode part are installed inside the chamber, and a processing method for the substrate is performed inside the chamber. However, during the processing method of the substrate, such as a forming operation of a thin film, a patterning operation of a thin film, etc., particles occur. The particles are attached on an inner wall of the chamber and dropped onto the substrate during following operations, thereby contaminating the substrate.

In order to prevent the contamination of the substrate, a cleaning operation is periodically performed to clean the inside of the chamber. However, since the cleaning operation s is performed after releasing a vacuum of the chamber and cooling the susceptor, the chamber is not adopted for the processing method during the cleaning operation. As a result, a productivity of the substrate is degraded.

### BRIEF SUMMARY OF THE INVENTION

The present invention has been made in an effort to solve the above-stated problems, and an aspect of the present invention provides a substrate processing apparatus capable of improving a product yield.

In an exemplary embodiment, the present invention provides a substrate processing apparatus which includes a chamber, a substrate processing part, and a particle remover.

In an exemplary embodiment, the chamber defines a reaction space into which a reaction gas is injected. The substrate processing part is installed in the reaction space and provided with a substrate disposed thereon. The substrate processing part processes the substrate using the reaction gas. The particle remover is positioned between a sidewall of the chamber and the substrate processing part and generates an electric field to absorb a particle generated when the substrate is processed.

According to an exemplary embodiment, the particle remover includes a dumper and an electron source part. The dumper is installed in the reaction space, receives a first voltage having a positive polarity and absorbs the particle. The electron source part is positioned between the sidewall and the substrate processing part, facing the dumper, and receives a second voltage having a negative polarity to generate the electric field between the dumper and the electron source part in a first direction equal to a longitudinal direction of the sidewall.

According to an exemplary embodiment, the electron source part receives the second voltage and emits an electron beam to the dumper. The electron beam includes negative charges that are attached to the particle in the electric field and guided to the dumper.

According to an exemplary embodiment, the electron source part is consecutively formed along the sidewall and includes a ring-like shape. According to another exemplary embodiment, the dumper is successively formed along the sidewall or includes a plurality of dumpers which are successively installed along the electron source part.

According to an exemplary embodiment, the substrate processing part includes a susceptor and an electrode part. The susceptor is positioned in the reaction space, having the substrate disposed thereon, and spaced apart from the sidewall of the chamber by a first distance. The electrode part is positioned in the reaction space, faces the susceptor while interposing the substrate therebetween, and reacts with reaction gas in response to a voltage to generate a plasma between the susceptor and the electrode part.

According to an exemplary embodiment, the substrate processing apparatus further includes a vacuum pump. The vacuum pump is connected to the dumper and absorbs the particle attached onto the dumper to drain the particle to the exterior.

According to an exemplary embodiment, the substrate processing apparatus further includes a connection line connected between the vacuum pump and the dumper to guide the particle attached onto the dumper to the vacuum pump.

In another exemplary embodiment, the present invention provides a substrate processing apparatus which includes a chamber, a susceptor, an electrode part, a dumper, and an electron source part.

The chamber defines a reaction space into which a reaction gas is injected. The susceptor is positioned in the reaction space and provided with a substrate disposed thereon. The electrode part is positioned in the reaction space and faces the susceptor while interposing the substrate therebetween. The electrode part reacts with the reaction gas in response to a first voltage and generates plasma between the substrate and the electrode part, thereby forming a thin film on the substrate. The dumper is positioned in the reaction space and receives a second voltage including a positive polarity to absorb a particle generated when forming the thin film. The electron source part is positioned between a sidewall of the chamber and the electrode part when viewed in a plan view and faces the dumper. The electron source part receives a third voltage including a negative polarity and emits an electron beam to the dumper to generate an electric field between the dumper and the electron source part.

In another exemplary embodiment, the present invention provides a substrate processing apparatus which includes a chamber, a susceptor, an electrode part, a dumper, and an electron source part.

The chamber defines a reaction space into which a reaction gas is injected. The susceptor is positioned in the reaction space and provided with a substrate disposed thereon. The electrode part is positioned in the reaction space and faces the susceptor while interposing the substrate therebetween. The electrode part reacts with the reaction gas in response to a first voltage and generates plasma between the substrate and the electrode part, thereby patterning a thin film on the substrate. The dumper is positioned in the reaction space and receives a second voltage including a positive polarity to absorb a particle generated when patterning the thin film. The electron source part is positioned between a sidewall of the chamber and the electrode part and faces the dumper. The electron source part receives a third voltage including a negative polarity and emits an electron beam to the dumper to generate an electric field between the dumper and the electron source part.

According to the above exemplary embodiments, the particle remover generates an electric field to guide the particle to the dumper. Thus, the substrate processing apparatus prevents the particle from being attached onto a sidewall of the chamber, thereby improving product yield and productivity and reducing manufacturing costs.

### BRIEF DESCRIPTION OF THE DRAWINGS

The above and/or other aspects, features, and advantages of the present invention will become more apparent by reference to the following detailed description when taken in conjunction with the accompanying drawings in which:

FIG. 1 is a plan view illustrating an exemplary embodiment of a substrate processing apparatus according to the present invention;

FIG. 2 is a cross-sectional view taken along a line I-I′ of FIG. 1;

FIG. 3 is a cross-sectional view illustrating an exemplary embodiment of a thin film formed using the substrate processing apparatus;

FIG. 4 is an enlarged cross-sectional view illustrating a particle remover of FIG. 2, according to the present invention;

FIG. 5 is a plan view illustrating an exemplary embodiment of a dumper of FIG. 2, according to the present invention;

FIG. 6 is a plan view illustrating another exemplary embodiment of a dumper of FIG. 2, according to the present invention;

FIG. 7 is a graph illustrating an exemplary embodiment of a Paschen-curve according to gases which generate plasma, according to the present invention;

FIG. 8 is a plan view illustrating another exemplary embodiment of a substrate processing apparatus according to the present invention; and

FIG. 9 is a cross-sectional view illustrating an exemplary embodiment of a thin film patterned by the substrate processing apparatus of FIG. 8, according to the present invention.

### DETAILED DESCRIPTION OF THE INVENTION

The present invention will now be described more fully hereinafter with reference to the accompanying drawings, in which embodiments of the invention are shown. This invention may, however, be embodied in many different forms and should not be construed as limited to the embodiments set forth herein. Rather, these embodiments are provided so that this disclosure will be thorough and complete, and will fully convey the scope of the invention to those skilled in the art. In the drawings, the size and relative sizes of layers and regions may be exaggerated for clarity.

It will be understood that when an element or layer is referred to as being “on”, “connected to” or “coupled to” another element or layer, it can be directly on, connected or coupled to the other element or layer or intervening elements or layers may be present. In contrast, when an element is referred to as being “directly on,” “directly connected to” or “directly coupled to” another element or layer, there are no intervening elements or layers present. Like numbers refer to like elements throughout. As used herein, the term “and/or” includes any and all combinations of one or more of the associated listed items.

It will be understood that, although the terms first, second, etc. may be used herein to describe various elements, components, regions, layers and/or sections, these elements, components, regions, layers and/or sections should not be limited by these terms. These terms are only used to distinguish one element, component, region, layer or section from another region, layer or section. Thus, a first element, component, region, layer or section discussed below could be termed a second element, component, region, layer or section without departing from the teachings of the present invention.

Spatially relative terms, such as “beneath”, “below”, “lower”, “above”, “upper” and the like, may be used herein for ease of description to describe one element or feature's relationship to another element(s) or feature(s) as illustrated in the figures. It will be understood that the spatially relative terms are intended to encompass different orientations of the device in use or operation in addition to the orientation depicted in the figures. For example, if the device in the figures is turned over, elements described as “below” or “beneath” other elements or features would then be oriented “above” the other elements or features. Thus, the exemplary term “below” can encompass both an orientation of above and below. The device may be otherwise oriented (rotated 90 degrees or at other orientations) and the spatially relative descriptors used herein interpreted accordingly.

The terminology used herein is for the purpose of describing particular embodiments only and is not intended to be limiting of the invention. As used herein, the singular forms, “a”, “an” and “the” are intended to include the plural forms as well, unless the context clearly indicates otherwise. It will be further understood that the terms “includes” and/or “including”, when used in this specification, specify the presence of stated features, integers, steps, operations, elements, and/or components, but do not preclude the presence or addition of one or more other features, integers, steps, operations, elements, components, and/or groups thereof.

Unless otherwise defined, all terms (including technical and scientific terms) used herein have the same meaning as commonly understood by one of ordinary skill in the art to which this invention belongs. It will be further understood that terms, such as those defined in commonly used dictionaries, should be interpreted as having a meaning that is consistent with their meaning in the context of the relevant art and will not be interpreted in an idealized or overly formal sense unless expressly so defined herein.

Hereinafter, the present invention will be explained in detail with reference to the accompanying drawings.

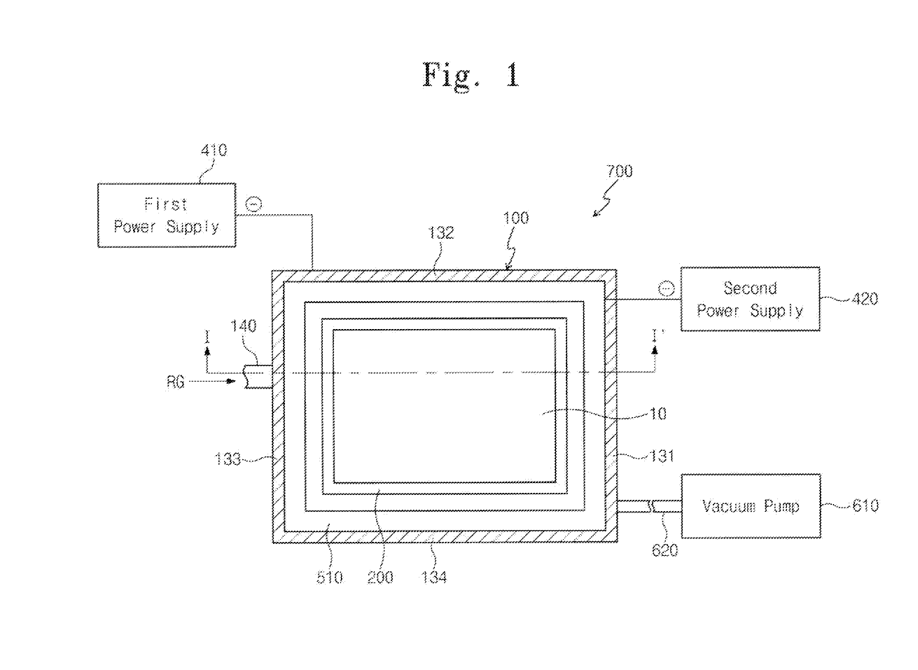

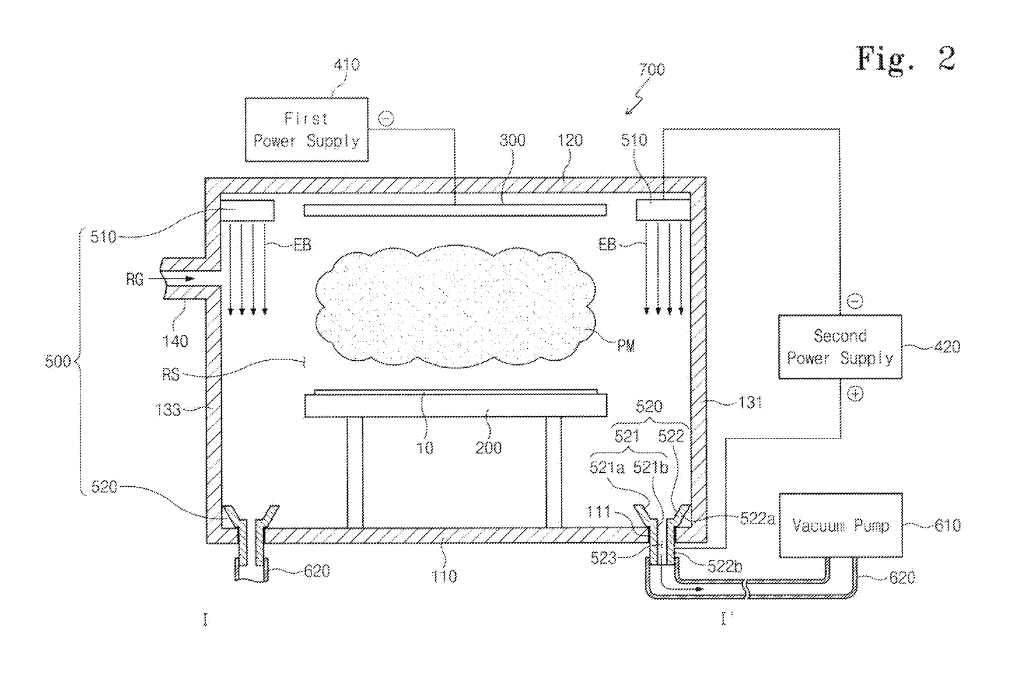

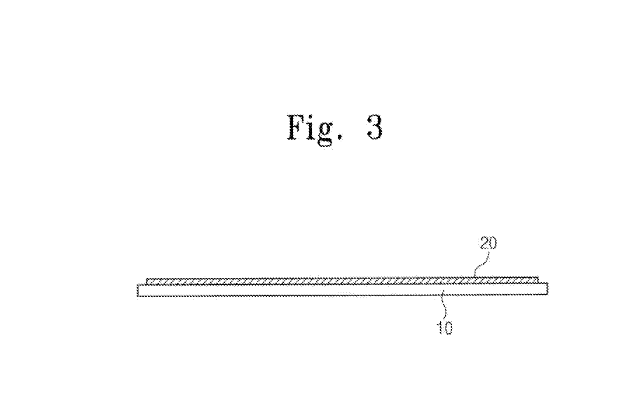

FIG. 1 is a plan view illustrating an exemplary embodiment of a substrate processing apparatus according to the present invention, FIG. 2 is a cross-sectional view taken along a line I-I′ of FIG. 1, and FIG. 3 is a cross-sectional view illustrating a thin film formed using the substrate processing apparatus, according to the present invention. In FIG. 1, a top portion 120 of a chamber 100 and an electrode part 300 of the chamber 100 are omitted in order to illustrate an interior of a substrate processing apparatus 700 in detail.

Referring to FIGS. 1 and 2, according to an exemplary embodiment, the substrate processing apparatus 700 includes the chamber 100, a substrate processing part which includes a susceptor 200 and an electrode part 300, first and second power supplies 410 and 420, and a particle remover 500.

The chamber 100 includes a bottom portion 110, a top portion 120 facing the bottom portion 110, and first, second, third and fourth sidewalls 131, 132, 133 and 134 extended from the bottom portion 110 to provide a reaction space RS into which a reaction gas RG is injected. The first, second, third and fourth sidewalls 131, 132, 133 and 134 are connected between the bottom portion 110 and the top portion 120. In the current exemplary embodiment the chamber 100 includes four sidewalls 131, 132, 133 and 134, however, the present invention is not limited hereto and the number of the sidewalls may be enhanced or reduced according to a structure of the chamber 100. According to an exemplary embodiment, when viewed in a plan view, the first, second, third and fourth sidewalls 131, 132, 133 and 134 are sequentially arranged along a counter-clockwise direction.

Also, the chamber 100 further includes an injection port 140 through which the reaction gas RG is injected. The injection port 140 is formed through the third sidewall 133 and the reaction gas RG is injected into the reaction space RS through the injection port 140.

The susceptor 200 is arranged in the reaction space RS and spaced apart from the first, second, third and fourth sidewalls 131, 132, 133 and 134. When a substrate 10 is positioned on the susceptor 200, the susceptor 200 generates heat sufficient to heat the substrate 10.

According to an exemplary embodiment, the electrode part 300 is disposed on the susceptor 200 such that the electrode part 300 faces the susceptor 200 while interposing the substrate 10 therebetween. The electrode part 300 is electrically connected to the first power supply 410 to receive a first voltage generated from the first power supply 410. The first voltage includes a negative polarity, so that the electrode part 300 also includes the negative polarity. On the contrary, since a voltage having a positive polarity is applied to the susceptor 200, the susceptor 200 includes the positive polarity. The electrode part 300 reacts with the reaction gas RG to form plasma PM between the electrode part 300 and the susceptor 200. In the current exemplary embodiment, the reaction gas RG may include argon (Ar) or nitride (N₂). Particularly, argon ions derived from the argon gas in a plasma state advance toward a target of the electrode part 300 having the negative polarity and collide with the target of the electrode part 300. Due to the physical collision between the target of the electrode part 300 and the argon ions, a sputtering occurs to move desired atoms physically. The sputtered atoms are dropped onto the substrate 10 and stacked on the substrate 10, so that a thin film 20 is formed on the substrate 10 as shown in FIG. 3.

In the current exemplary embodiment, the substrate processing apparatus 700 forms the thin film 20 using the sputtering method, however, the present invention is not limited hereto and the thin film 20 may be formed by a plasma-enhanced chemical vapor deposition (“PECVD”) method, for example. In this case, the reaction gas RG includes substances as materials for the thin film 20, and the susceptor 200 is grounded in order to minimize sputtering effects caused by ion collision.

As described above, since the substrate processing apparatus 700 forms the thin film 20 using the sputtering method, particles generated during the sputtering method may be attached on the first, second, third and fourth sidewalls 131, 132, 133 and 134.

According to an exemplary embodiment, the particle remover 500 arranged in the reaction space RS prevents the particles from being attached on the first, second, third and fourth sidewalls 131, 132, 133 and 134.

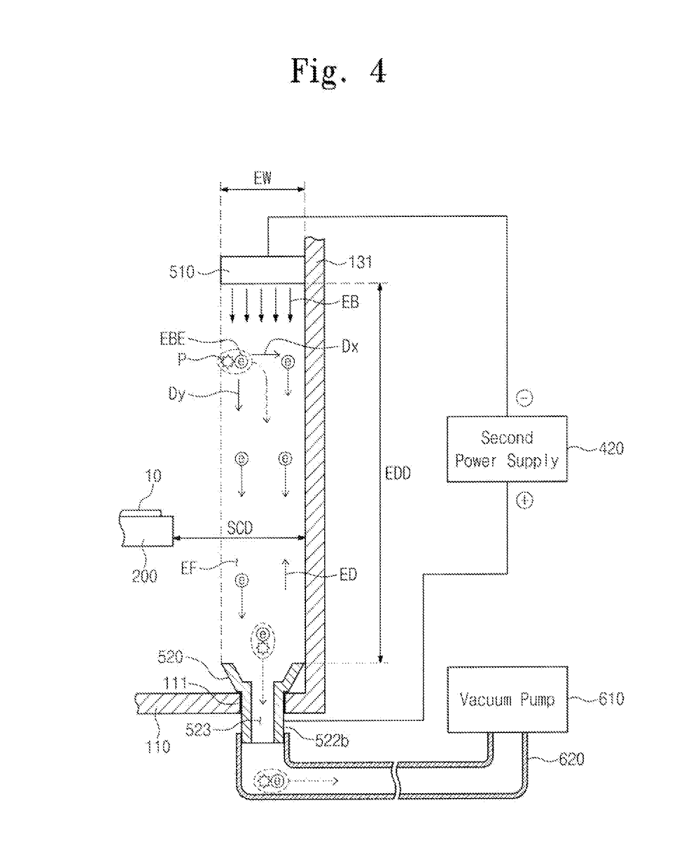

FIG. 4 is an enlarged cross-sectional view illustrating an exemplary embodiment of a particle remover of FIG. 2, according to the present invention.

Referring to FIGS. 2 and 4, the particle remover 500 includes an electron source part 510 which emits an electron beam EB, and a dumper 520 which absorbs the particles P advancing toward the first, second, third and fourth sidewalls 131, 132, 133 and 134.

Referring to FIGS. 1 and 2, the electron source part 510 is positioned adjacent to the electrode part 300 and above the dumper 520. When viewed in a plan view, the electron source part 510 surrounds the susceptor 200 and is spaced apart from the susceptor 200. The electron source part 510 is successively formed along the first, second, third and fourth sidewalls 131, 132, 133 and 134 and includes a ring-like shape. The electron source part 510 is positioned between the susceptor 200 and the first, second, third and fourth sidewalls 131, 132, 133 and 134. In the current exemplary embodiment, the electron source part 510 makes contact with the first, second, third and fourth sidewalls 131, 132, 133 and 134, however, the present invention is not limited hereto, and the electron source part 510 may be spaced apart from the first, second, third and fourth sidewalls 131, 132, 133 and 134.

The electron source part 510 is electrically connected to the second power supply 420 and receives a second voltage having the negative polarity from the second power supply 420 to emit the electron beam EB to the dumper 520. Thus, an electron beam curtain is formed inward the first, second, third and fourth sidewalls 131, 132, 133 and 134, and the electron beam EB surrounds the susceptor 200.

The dumper 520 is positioned corresponding to the electron source part 510, so that the dumper 520 faces the electron source part 510.

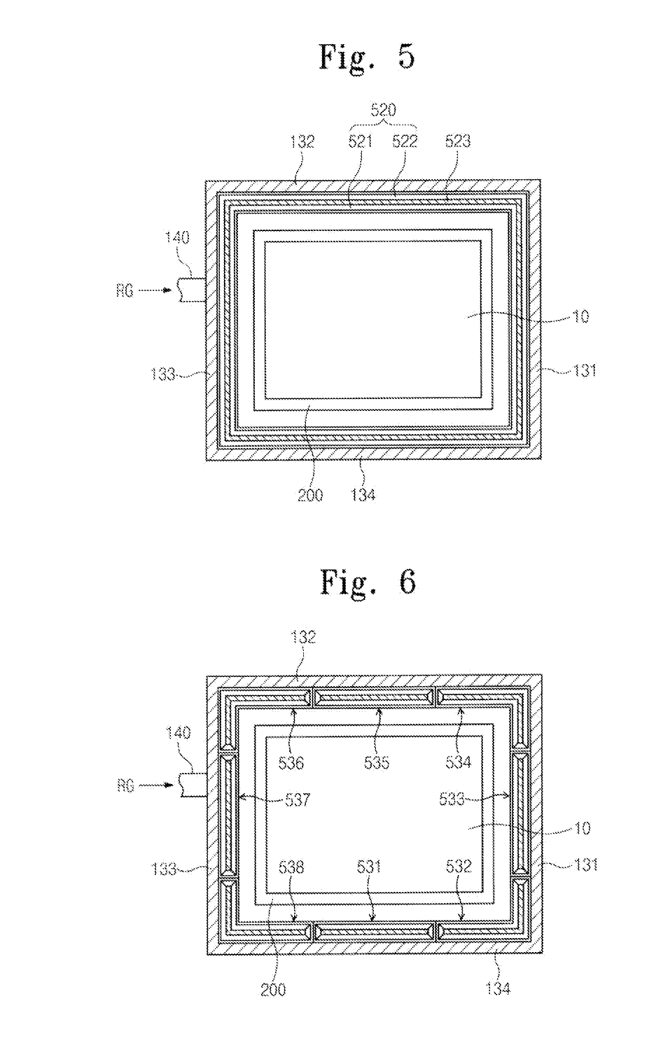

FIG. 5 is a plan view illustrating an exemplary embodiment of a dumper of FIG. 2, according to the present invention.

Referring to FIGS. 2 and 5, the dumper 520 is electrically connected to the second power supply 420 and receives a third voltage having the positive polarity from the second power supply 420. According to an exemplary embodiment, the third voltage includes a same absolute voltage level as the second voltage.

The dumper 520 is positioned adjacent to the bottom portion 110 of the chamber 100 and consecutively formed along the electron source part 510. Further, according to an exemplary embodiment, the dumper 510 includes a first absorber 521 and a second absorber 522 facing the first absorber 521. The first absorber 521 includes a wing portion 521a onto which the particles P are attached and a guide portion 521b which extends from the wing portion 521a to guide the particles P. The wing portion 521a is positioned inside the reaction space RS and faces the electron source part 510. The guide portion 521b provides a path through which the particles P induced to the wing portion 521a are drained. In the current exemplary embodiment, the first and second absorbers 521 and 522 have the same structure, that is, the second absorber 522 also includes a wing portion 522a and a guide portion 522b same as that of the first absorber 521, therefore, the detailed description of the second absorber 522 will be omitted.

According to an exemplary embodiment, the second absorber 522 is symmetrical with the first absorber 521 with reference to an imaginary line passing through between the first and second absorbers 521 and 522. The guide portion 521b of the first absorber 521 is spaced apart from a guide portion 522b of the second absorber 522, and the particles P are drained through the path defined by the guide portions 521b and 522b.

The chamber 100 includes a hole 111 formed through the bottom portion 110, into which the guide portions 521b and 522b are inserted. The guide portions 521b and 522b are outwardly exposed through the hole 111.

FIG. 6 is a plan view illustrating another exemplary embodiment of a dumper of FIG. 2, according to the present invention.

Referring to FIG. 6, a dumper according to another exemplary embodiment of the present invention includes a plurality of dumpers 531 through 538 to surround the susceptor 200 when viewed in a plan view. Each dumper 531 through 538 is positioned at position same as that of the dumper 520 shown in FIGS. 2 and 5, and thus the detailed description of each dumper 531 through 538 will be omitted.

The dumpers 531 through 538 include first through eighth dumpers 531 through 538, however, the present invention is not limited hereto and the number of the dumpers may be enhanced or reduced according to a size of the chamber 100.

According to an exemplary embodiment, the first through eighth dumpers 531 through 538 are consecutively arranged along the electron source part 510 (see FIG. 2) and include a same vertical sectional view as that of the dumper 520 shown in FIGS. 2 and 4.

Referring to FIGS. 2 and 4, when the electron beam EB is emitted from the electron source part 510, an electric field EF is generated between the electron source part 510 and the dumper 520. In detail, the second voltage having the negative polarity is applied to the electron source part 510 and the third voltage having the positive polarity is applied to the dumper 520. Accordingly, the electric field EF is formed from the dumper 520 to the electron source part 510.

Hereinafter, an operation wherein the particles P are induced to the dumper 520 in the electric field EF will be described in detail.

When the particles P are flowed into the electric field EF, electrons EBE of the electron beam EB are attached to the particles P. Since the electrons EBE moves to the positive polarity from the negative polarity, the particles P are induced to the dumper 520 by the electric field EF. Therefore, the particles P may be attached onto the dumper 520 without attaching onto the first, second, third and fourth sidewalls 131, 132, 133 and 134.

In order to allow the particles P flowed into the electric field EF to be attached onto the dumper 520 without attaching onto the first, second, third and fourth sidewalls 131, 132, 133 and 134, a condition is required which allows a time during which the particles P reach to the dumper 520 to be shorter than a time during which the particles P reach adjacent sidewalls thereto. The electric field EF includes an intensity suitable for the condition.

Hereinafter, a range of the intensity of the electric field EF will be described in detailed with reference to following equations.

The particles P perform a uniformly accelerated motion in a first direction Dy same as a direction along which the electrons EBE move within the electric field EF, and perform a uniform motion in a second direction Dx substantially perpendicular to a direction ED of the electric field EF. That is, the particles P perform the uniformly accelerated motion in the first direction Dy closed to the dumper 520, and perform the uniform motion in the second direction Dx closed to adjacent sidewall of the first, second, third and fourth sidewalls 131, 132, 133 and 134. Hereinafter, a case where the particles P are adjacent to the first sidewall 131 will be described as an example.

In the electric field EF, a distance where the particles P move along the first direction Dy is obtained by a following equation 1.

$$MD = ( Vy \times Td ) + ( \frac{1}{2} \times Pa \times {Td}^{2} ) \qquad 1$$

In equation 1, MD represents the distance where the particles P move along the first direction Dy, Vy represents a second speed (i.e. a speed per second) where the particles P move along the first direction Dy in the electric field EF, Td represents a time needed that the particles P reach to the dumper 520, and Pa represents an acceleration of the particles P in the electric field EF. Hereinafter, the time Td needed for the particles P to reach the dumper 520 is defined as a first time Td.

Referring to FIG. 4 and equation 1, a first value is calculated by multiplying the second speed Vy where the particles P move along the first direction Dy in the electric field EF by the first time Td, and a second value is calculated by dividing a value that is obtained by multiplying a squared value of the first time Td by the acceleration Pa of the particles P corresponding to the first direction Dy by 2. Then, when the first value is added to the second value, the distance MD where the particles P move along the first direction Dy may be calculated.

According to an exemplary embodiment, the acceleration Pa of the particles P is calculated by a following equation 2.

$$Pa = \frac{Q \times E}{PM} \qquad 2$$

In equation 2, Q represents a charge amount of the electric field EF, E represents the intensity of the electric field EF, and PM represents a mass of the particles P.

Referring to FIG. 4 and equation 2, the acceleration Pa is calculated by dividing a value that is obtained by multiplying the charge amount Q by the intensity E of the electric field EF by the mass PM of the particles P. When using equation 2, a following equation 3 is obtained from equation 1.

$$MD = ( Vy \times Td ) + ( \frac{1}{2} \times \frac{Q \times E}{PM} \times {Td}^{2} ) \qquad 3$$

Referring to FIG. 4 and equation 3, the distance MD where the particles P move along the first direction Dy may be calculated by using the intensity E of the electric field EF, and thus the intensity E of the electric field EF may be calculated from equation 3.

The electric field EF includes the intensity E which satisfies the condition allowing the first time Td during which the particles P reach to the dumper 520 to be shorter than the time during which the particles P reach to adjacent sidewalls thereto. Thus, the electric field EF includes the intensity greater than the intensity which satisfies the condition allowing the time during which the particles P reach to adjacent sidewalls to be shorter than the first time Td during which the particles P reach to the dumper 520. Hereinafter for the convenience of the description, the intensity E which makes the particles P to reach to the dumper 520 prior to the first sidewall 131 is defined as a first intensity the intensity E which makes the particles P to reach to the first sidewall 131 prior to the dumper 520 is defined as a second intensity, and a time needed that the particles P reach to the first sidewall 131 is defined as a second time.

When the second speed Vy where the particles P move along the first direction Dy is zero, the second intensity obtained using equation 3 is calculated as a following equation 4.

$$E 2 = \frac{2 \times PM \times MD}{Q \times {Tw}^{2}} \qquad 4$$

In equation 4, E2 represents the second intensity, and Tw represents the second time.

Referring to FIG. 4 and equation 4, in order to calculate the second intensity E2, a third value is calculated by duplicating a value that is obtained by multiplying the mass PM of the particles P by the distance MD where the particles P move along the first direction Dy, and a fourth value is calculated by multiplying a squared value of the second time Tw by the charge amount Q. When the third value is divided by the fourth value, the second intensity E2 may be calculated.

According to an exemplary embodiment, since the particles P perform the uniform motion, the second time Tw needed that the particles P reach to the first sidewall 131 in the electric field EF is calculated by a following equation 5.

$$Tw = \frac{EW}{Vx} \qquad 5$$

In equation 5, EW represents a width EW of the electron beam 510, and Vx represents a speed of the particles P moving along the second direction Dx.

Referring to FIG. 4 and equation 5, the second time Tw is calculated by dividing a moved distance of the particles P along the second direction Dx by a moved speed Vx of the particles P along the second direction Dx. The moved distance of the particles P along the second direction Dx is equal to the width EW of the electron beam 510, so that the first time Tw corresponds with a value obtained by the width EW of the electron beam 510 by the speed Vx corresponding to the second direction Dx.

Thus, when equation 5 is substituted into equation 4, a range of the second intensity is calculated as a following equation 6.

$$E 2 = \frac{2 \times MD \times PM \times {Vx}^{2}}{Q \times {EW}^{2}} \qquad 6$$

In equation 6, a maximum distance where the particles P move along the first direction Dy in the electric field is equal to a distance EDD between the electron source part 510 and the dumper 520. Accordingly, the range of the first intensity E1, that is, the intensity range of the electric field EF is as a following equation 7.

$$E 1 > \frac{2 \times EDD \times PM \times {Vx}^{2}}{Q \times {EW}^{2}} \qquad 7$$

In equation 7, E1 represents the first intensity, and the EDD represents the distance between the electron source part 510 and the dumper 520.

Referring to FIG. 4 and equations 6 and 7, the first intensity E1 of the electric field EF is greater than the second intensity E2 of the electric field EF, and the second intensity E2 depends upon the moved distance MD of the particles P and the width EW of the electron source part 510. Thus, a minimum intensity of the electric field EF may be varied according to the distance EDD between the electron source part 510 and the dumper 520 and the width EW of the electron source part 510. That is, the particle remover 500 may adjust the distance EDD between the electron source part 510 and the dumper 520 and the width EW of the electron source part 510, thereby controlling the first intensity E1 of the electric field EF.

The second intensity E2 is reduced as the width EW of the electron source part 510 increases. Thus, the minimum intensity of the electric field EF is reduced as the width EW of the electron source part 510 increases, so that the intensity range of the electric field EF is expanded.

However, when the width EW of the electron source part 510 is large, an area in which the electric field EF is formed may be overlapped with an area in which the plasma PM is formed. In order to prevent this problem, the electron source part 510 includes the width EW narrower than a distance SCD between the susceptor 200 and the first sidewall 131. Also, the width EW of the electron source part 510 is narrower than a distance between the susceptor 200 and the second, third or fourth sidewall 132, 133 and 134 (see FIG. 1).

As described above, when the first intensity E1 of the electric field EF is greater than the second intensity E2, the particles P are attached onto the dumper 520 without attaching onto the first sidewall 131. However, when the first intensity E1 of the electric field EF is large, a discharge occurs, thereby causing an arc. Therefore, the electric field EF includes an intensity lower than intensity corresponding to a breakdown voltage where the discharge starts. Hereinafter, the intensity corresponding to the breakdown voltage is defined as a “third intensity” for the convenience of the description.

According to an exemplary embodiment, the breakdown voltage is varied according to a type of the plasma gas generating the plasma, a pressure of a space where the plasma gas is filled, and the distance between negative and positive electrodes for the electric field. According to an exemplary embodiment, the variation of the breakdown voltage may be illustrated by a Paschen-curve. The Paschen-curve represents a mutual relation between the breakdown voltage and the value obtained by multiplying the distance by the pressure.

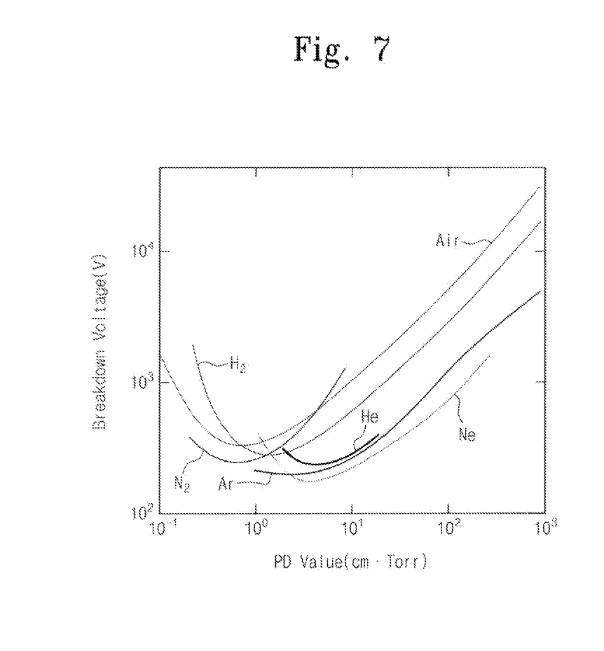

FIG. 7 is a graph illustrating a Paschen-curve according to gases which generate plasma.

Referring to FIG. 7, the breakdown voltage depends on a value PD obtained by multiplying the pressure by the distance between two electrodes. In FIG. 7, Paschen-curves for gases such as helium (He), neon (Ne), argon (Ar), nitride (N2), hydrogen (H2) and air have been shown. As shown in FIG. 7, although the value PD is not varied, the breakdown voltage is varied according to a kind of plasma gases.

Referring to FIGS. 4 and 7, the breakdown voltage depends on the pressure, the distance between the electrodes, and the plasma gases. Thus, the particle remover 500 adjusts the distance EDD between the electron source part 510 and the dumper 520 based on the type of gases injected into the chamber 100 and the pressure in the chamber 100, thereby preventing the discharge due to the electric field EF.

As described above, the particle remover 500 removes the particles P using the electric field EF that is generated adjacent to the first, second, third and fourth sidewalls 131, 132, 133 and 134. Accordingly, the particle remover 500 prevents the particles P from being attached onto the first, second, third and fourth sidewalls 131, 132, 133 and 134 and defects due to the particles P. As a result, the cleaning operation for the chamber 100 may be extended, and the product yield and productivity increase. Further, according to an exemplary embodiment, the particle remover 500 may control the intensity of the electric field EF, so that the discharge caused by the electric field EF may be prevented, thereby increasing the product yield.

Referring to FIGS. 2 and 4, according to an exemplary embodiment, the substrate processing apparatus 700 further includes a vacuum pump 610 and a connection line 620 in order to drain the particles P.

The vacuum pump 610 is installed outside the chamber 100 and absorbs the particles P induced to the dumper 520 using a vacuum. Also, the vacuum pump 610 adjusts an absorbing force thereof to control the pressure in the chamber 100. According to an exemplary embodiment, the connection line 620 is connected between the dumper 520 and the vacuum pump 610 and guides the particles P induced to the dumper 520 to the vacuum pump 610. That is, end portions, which are exposed outside the chamber 100, of the guide portions 521b and 522b of the dumper 520 are inserted into the connection line 620. Thus, the particles P induced to the dumper 520 are sucked into a space 523 between the guide portions 521b and 522b by the absorbing force and moved to the vacuum pump 610 through the connection line 620. Consequently, according to the current embodiment, the substrate processing apparatus 700 does not need to perform the cleaning operation, so that the productivity may be enhanced and the manufacturing cost may be reduced.

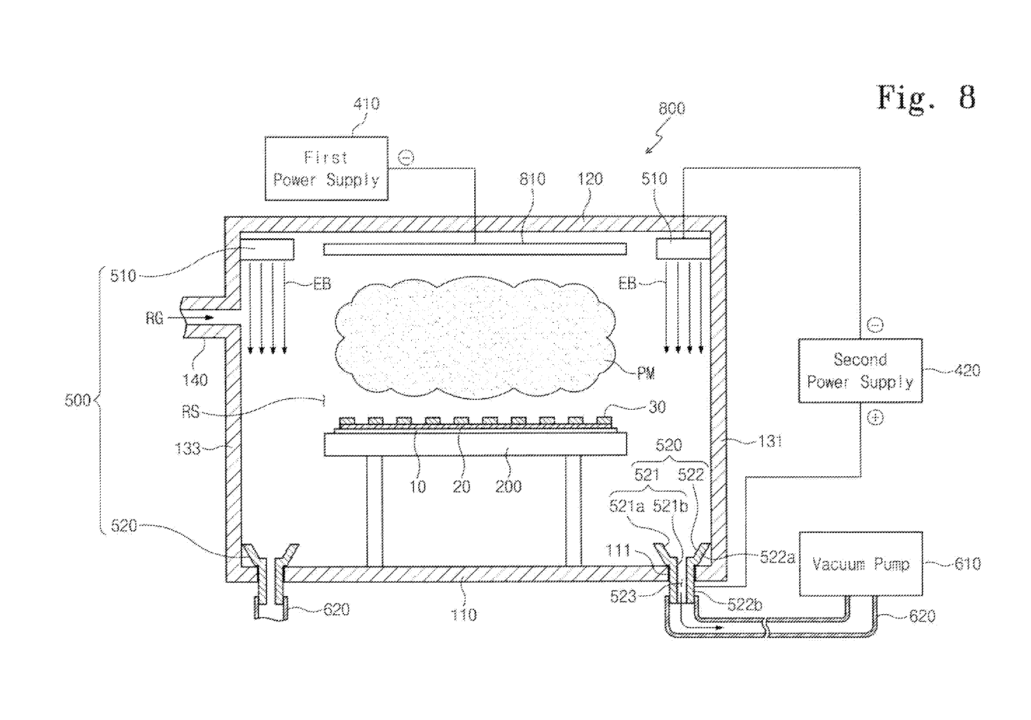

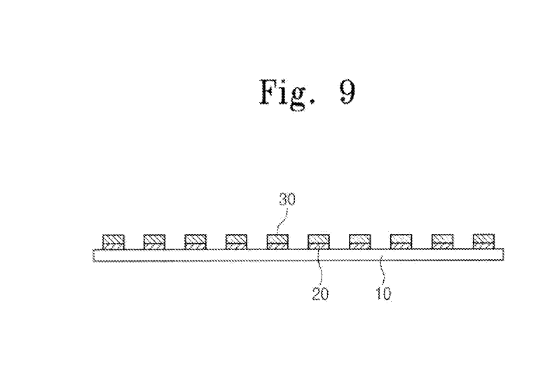

FIG. 8 is a plan view illustrating another exemplary embodiment of a substrate processing apparatus according to the present invention, and FIG. 9 is a cross-sectional view illustrating a thin film patterned by the substrate processing apparatus of FIG. 8. In FIG. 8, the same reference numerals denote the same elements in FIG. 2, and thus the detailed descriptions of the same elements will be omitted.

Referring to FIG. 8, a substrate processing apparatus 800 includes a chamber 100, a substrate processing part which includes a susceptor 200 and an electrode part 810, a first power supply 410, a second power supply 420, and a particle remover 500. In the current exemplary embodiment, the substrate processing apparatus 800 etches a thin film 20 using a plasma PM.

According to an exemplary embodiment, the chamber 100 defines a reaction space RS and a reaction gas RG is injected into the reaction space RS. The susceptor 200 on which a substrate 10 is disposed is positioned inside the reaction space RS. The thin film 20 is formed on the substrate 10, and a photoresist pattern 30 is formed on the thin film 20.

According to an exemplary embodiment, the electrode part 300 faces the susceptor 200 in the reaction space RS while interposing the substrate 10 therebetween. The electrode part 300 is electrically connected to the first power supply 410 and receives a first voltage having a negative polarity from the first power supply 410.

When the first voltage is applied to the electrode part 300, the plasma PM is generated by the reaction gas RG. The plasma PM provides positive ions which are accelerated toward the substrate 10. The positive ions collide with the thin film 20, so that portions of the thin film 10, which are not protected by the photoresist pattern 30, are physically removed, thereby etching the thin film 20 corresponding to the photoresist pattern 30.

According to an exemplary embodiment, the particle remover 500 is positioned inside the reaction space RS and adjacent to the first, second, third and fourth sidewalls 131, 132, 133 and 134 of the chamber 100. When the electric field is generated adjacent to the first, second, third and fourth sidewalls 131, 132, 133 and 134, the electric field guides the particles generated during the patterning process for the thin film 20 to the dumper 520 of the particle remover 500. Thus, the particles are not attached onto the first, second, third and fourth sidewalls 131, 132, 133 and 134 of the chamber 100, so that the product yield and the productivity may be improved.

Further, according to an exemplary embodiment, the substrate processing apparatus 800 further includes a vacuum pump 610 and a connection line 620 in order to drain the particles guided to the dumper 520. The particles guided to the dumper 520 are sucked by the vacuum pump 610 and drained to the exterior. As a result, the substrate processing apparatus 800 does not need to perform the cleaning operation, so that the productivity may be enhanced and the manufacturing cost may be reduced.

According to the above, the electric field EF is generated in a region adjacent to the first, second, third and fourth sidewalls 131, 132, 133 and 134 of the chamber 100 by the particle remover 500, and the electric field EF guides the particles P to the dumper 520. Thus, the substrate processing apparatus 700, 800 prevents the particles P from being attached onto the sidewalls, thereby preventing the defects of the substrate, enhancing the productivity, and reducing the manufacturing cost.

In addition, the vacuum pump 610 absorbs the particles P guided to the dumper 520, so that the particles P may be drained to an exterior of the chamber 100. Consequently, the substrate processing apparatus 700, 800 does not need to perform the cleaning operation, so that the productivity may be enhanced and the manufacturing cost may be reduced.

While the present invention has been shown and described with reference to some exemplary embodiments thereof, it should be understood by those of ordinary skill in the art that various changes in form and details may be made therein without departing from the spirit and scope of the present invention as defined by the appended claims.

What is claimed is:

1. A substrate processing apparatus comprising:
a chamber which defines a reaction space into which a reaction gas is injected;
a substrate processing part installed in the reaction space and comprising a substrate disposed thereon, which processes the substrate using the reaction gas; and
a particle remover positioned between a sidewall of the chamber and the substrate processing part, which generates an electric field, and absorbs a particle generated when the substrate is processed.

2. The substrate processing apparatus of claim 1, wherein the particle remover comprises:
a dumper installed in the reaction space, which receives a first voltage having a positive polarity, and absorbs the particle; and
an electron source part positioned between the sidewall and the substrate processing part facing the dumper, which receives a second voltage having a negative polarity to generate the electric field between the dumper and the electron source part in a first direction equal to a longitudinal direction of the sidewall.

3. The substrate processing apparatus of claim 2, wherein the electron source part receives the second voltage and emits an electron beam to the dumper.

4. The substrate processing apparatus of claim 3, wherein the electron beam comprises negative charges attached to the particle in the electric field and guided to the dumper.

5. The substrate processing apparatus of claim 2, wherein the electric field comprises an intensity satisfying a following equation,
$$E > \frac{2 \times EDD \times PM \times {Vx}^{2}}{Q \times {EW}^{2}}$$
wherein E represents the intensity of the electric field, EDD represents a distance between the electron source part and the dumper, PM represents a mass of the particle, Vx represents a speed of the particle moving along a second direction substantially perpendicular to the first direction, Q represents a charge amount of the electric field, and EW represents a length of a portion of the electron source part, which is protruded from the sidewall and extended to the substrate processing part.

6. The substrate processing apparatus of claim 5, wherein the electric field comprises an intensity smaller than an intensity which satisfies a breakdown voltage calculated corresponding to the reaction gas according to a pressure in the chamber and the distance between the electron source part and the dumper.

7. The substrate processing apparatus of claim 6, wherein the breakdown voltage is calculated based on a Paschen-curve.

8. The substrate processing apparatus of claim 6, wherein the intensity of the electric field is adjusted by a protruded length of the electron source part.

9. The substrate processing apparatus of claim 8, wherein the intensity of the electric field is adjusted by the distance between the electron source part and the dumper.

10. The substrate processing apparatus of claim 9, wherein the distance between the electron source part and the dumper satisfies a following equation,
$$EDD = ( Vy \times Td ) + ( \frac{1}{2} \times Pa \times {Td}^{2} )$$
where Vy represents a second speed (a speed per second) where the particle moves to the dumper, Td represents a time needed for the particle to reach to the dumper, and Pa represents an acceleration of the particle in the electric field.

11. The substrate processing apparatus of claim 2, wherein the substrate processing part comprises:
a susceptor positioned in the reaction space comprising the substrate disposed thereon, and spaced apart from the sidewall of the chamber by a first distance; and
an electrode part positioned in the reaction space, facing the susceptor while interposing the substrate therebetween, which reacts with the reaction gas in response to a voltage and generates a plasma between the susceptor and the electrode part.

12. The substrate processing apparatus of claim 11, wherein the electron source part is protruded from the sidewall to the electrode part, and a protruded length thereof is narrower than the first distance.

13. The substrate processing apparatus of claim 12, wherein the electron source part is spaced apart from the electrode part.

14. The substrate processing apparatus of claim 2, wherein the electron source part is consecutively formed along the sidewall and comprises a ring-like shape.

15. The substrate processing apparatus of claim 14, wherein the dumper is successively formed along the sidewall.

16. The substrate processing apparatus of claim 14, wherein the dumper comprises a plurality of dumpers which are successively installed along the electron source part.

17. The substrate processing apparatus of claim 2, further comprising a vacuum pump connected with the dumper, which absorbs the particle attached onto the dumper and drains the particle to the exterior.

18. The substrate processing apparatus of claim 17, further comprising a connection line connected between the vacuum pump and the dumper, which guides the particle attached onto the dumper to the vacuum pump.

19. The substrate processing apparatus of claim 2, wherein the first and second voltages comprise a same voltage level.

20. The substrate processing apparatus of claim 1, wherein the substrate processing part forms a thin film on the substrate using a sputtering method or a plasma-enhanced chemical vapor deposition method, and patterns the thin film formed on the substrate using a dry etching method.

21. A substrate processing apparatus comprising:
a chamber which defines a reaction space into which a reaction gas is injected;
a susceptor installed in the reaction space and comprising a substrate disposed thereon, which processes the substrate using the reaction gas; and
a particle remover which generates an electric field, and absorbs a particle generated when the substrate is processed.

22. The substrate processing apparatus of claim 21, wherein the particle remover comprises:
a dumper installed in the reaction space, which receives a first voltage including a positive polarity, and absorbs the particle; and
an electron source part positioned between a sidewall of the chamber and the susceptor, facing the dumper, which receives a second voltage including a negative polarity to generate the electric field between the dumper and the electron source part in a longitudinal direction of the sidewall.

23. The substrate processing apparatus of claim 22, wherein the dumper comprises:
a first absorber and a second absorber facing the first absorber, each comprising:
a wing portion onto which the particle is attached, and
a guide portion which extends from the wing portion to guide the particle.

24. The substrate processing apparatus of claim 23, wherein the wing portion is positioned inside the reaction space and faces the electron source part, and the guide portion provides a path through which the particle induced to the wing portion is drained to an exterior of the chamber.
